(19) United States
(12) Patent Application Publication
(10) Pub. No.: US 2012/0054414 A1
(43) Pub. Date: Mar. 1, 2012

(54) SOLID STATE DRIVE AND DATA CONTROL METHOD THEREOF

(75) Inventors: Song-Feng Tsai, Hsinchu (TW); Jen-Yu Hsu, Hsinchu (TW); Ling-Feng Chen, Hsinchu (TW)

(73) Assignee: LITE-ON IT CORP., Taipei City (TW)

(21) Appl. No.: 12/951,384

(22) Filed: Nov. 22, 2010

(30) Foreign Application Priority Data
Sep. 1, 2010 (CN) 201010271335.9

(51) Int. Cl. G06F 12/00; G06F 12/02; G11C 16/34

(52) U.S. Cl. 711/103; 711/E12.001; 711/E12.008

(57) ABSTRACT

A solid state drive includes a flash memory and a controlling unit. The flash memory includes plural blocks. Each block includes plural pages. The controlling unit is in communication with the flash memory. When data of a specified block are erased or data are written into the specified block, the controlling unit provides a time parameter to the specified block. The controlling unit performs a data loss prevention, a wear leveling operation or a garbage collection according to the time parameter.

This application claims the benefit of People's Republic of China application Serial No. 201010271335.9, filed Sep. 1, 2010, the subject matter of which is incorporated herein by reference.

### FIELD OF THE INVENTION

The present invention relates to a solid state drive, and more particularly to a data control method of a solid state drive.

### BACKGROUND OF THE INVENTION

As is well known, a solid state drive (SSD) is a data storage device that uses a NAND flash memory to store data. The NAND flash memory is a non-volatile memory. After data are written to the NAND flash memory, if no power is supplied to the flash memory, the data are still retained in the flash memory.

FIG. 1 is a schematic functional block diagram illustrating a conventional solid state drive. As shown in FIG. 1, the solid state drive 10 comprises a controlling unit 101 and a flash memory 105. The flash memory 105 is accessible by the controlling unit 101 through an internal bus 107. In addition, the controlling unit 101 is in communication with a host 12 through an external bus 20 to exchange instructions and data between the controlling unit 101 and the host 12. For example, the external bus 20 is a USB bus, an IEEE 1394 bus, an SATA bus, or the like.

Generally, the flash memory 105 comprises many blocks. Each block consists of a number of pages (or sectors), for example 64 pages. Each page is typically 4K bytes in size. Due to the inherent properties of the flash memory 105, the writing operation is performed in a page at a time, and the erasing operation is performed in a block-wise fashion.

Generally, each block of the flash memory 105 has limited erase count. For prolonging the service life of the flash memory 105, a wear leveling technique is disclosed. According to the wear leveling technique, the writing operations across all available blocks of the flash memory 105 are balanced in order to prevent overuse of specified blocks (high erase counts) and occurrence of bad blocks. In such way, the service life of the flash memory 105 may be prolonged.

For performing the wear leveling operation, the conventional solid state drive 10 uses the controlling unit 101 to detect the erase count of each block of the flash memory 105 and exchange data between the high-erase-count block and the low-erase-count block.

Moreover, after many times of writing and reading operations, each block of the flash memory 105 may contain valid pages and invalid pages. The data of the valid pages can be read out again. Whereas, the data of the invalid pages are no longer available.

Since the erasing operation of the flash memory 105 is performed in a block-wise fashion, the block containing the valid pages cannot be erased by the controlling unit 101. For effectively managing the data of each block, a garbage collection algorithm is provided. The garbage collection algorithm is a process of collecting valid pages of an old block and rewriting the valid pages into another new block. After the valid pages are collected, the old block may be erased and reused. Generally, the old block having a lower erase count will be preferentially erased. In addition, when the number of valid pages is lower than a threshold value, the garbage collection will be performed again.

From the above discussions, it is found that the erase count of each block needs to be detected by the controlling unit 101 of the solid state drive 10. In addition, the erase count of each block is used as an index. According to the index, the controlling unit 101 will determine whether the wear leveling operation or the garbage collection is performed.

Recently, as the size of the semiconductor is gradually reduced, the size of each memory cell of the flash memory 105 is downsized to 30 nm. After the data are written into the flash memory 105 for a time period (e.g. shorter than 3 months), the stored data of the memory cell are possibly lost.

### SUMMARY OF THE INVENTION

Therefore, the object of the present invention is to provide a data control method of a solid state drive. The data control method uses a time parameter as an index to perform data loss prevention, so that the possibly-lost data are moved to a new block to prevent data loss. In addition, according to the time parameter serving as the index, either the wear leveling operation or the garbage collection is performed.

The present invention provides a solid state drive. The solid state drive includes a flash memory and a controlling unit. The flash memory includes plural blocks. Each block includes plural pages. The controlling unit is in communication with the flash memory. When data of a specified block are erased or data are written into the specified block, the controlling unit provides a time parameter to the specified block. The controlling unit performs a data loss prevention, a wear leveling operation or a garbage collection according to the time parameter.

The present invention also provides a data control method of a flash memory. The flash memory includes plural blocks. Each block includes plural pages. The data control method includes the following steps. When data of the specified block are erased or data are written into the specified block, a time parameter is provided to the specified block. Then, a data loss prevention, a wear leveling operation or a garbage collection is performed according to the time parameter.

### BRIEF DESCRIPTION OF THE DRAWINGS

The above objects and advantages of the present invention will become more readily apparent to those ordinarily skilled in the art after reviewing the following detailed descriptions and accompanying drawings, in which:

FIG. 1 is a schematic functional block diagram illustrating a conventional solid state drive;

FIG. 2 is a schematic functional block diagram illustrating a solid state drive according to an embodiment of the present invention;

FIG. 3 is a flowchart illustrating a process of performing data loss prevention by using a time parameter according to an embodiment of the present invention;

FIG. 4 is a flowchart illustrating a process of performing a wear leveling operation by using the time parameter according to an embodiment of the present invention; and

FIG. 5 is a flowchart illustrating a process of performing a garbage collection by using the time parameter according to an embodiment of the present invention.

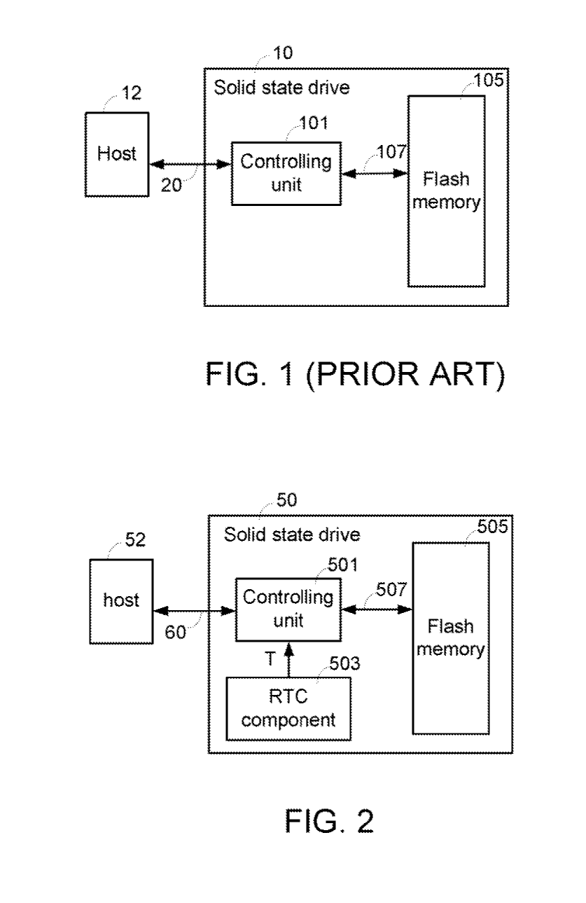

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

FIG. 2 is a schematic functional block diagram illustrating a solid state drive according to an embodiment of the present invention. As shown in FIG. 2, the solid state drive 50 comprises a controlling unit 501 and a flash memory 505. The flash memory 505 is accessible by the controlling unit 501 through an internal bus 507. In addition, the controlling unit 501 is in communication with a host 52 through an external bus 60 to exchange instructions and data between the controlling unit 501 and the host 52. Moreover, the solid state drive 50 further comprises a real time clock (RTC) component 503. The real time clock component 503 may issue a time signal T to the controlling unit 501. An example of the external bus 60 includes but is not limited to a USB bus, an IEEE 1394 bus or an SATA bus.

In an embodiment, the controlling unit 501 may provide a time parameter. In addition, the time signal T generated by the real time clock component 503 is used as the time parameter. For example, the time parameter is a time information including year, month, day, hour, minute and second. Of course, the time parameter will increase progressively without being zeroed. When data stored in any block of the flash memory 505 are erased or data are written into any block of the flash memory 505, the time parameter corresponding to the block will be recorded in the block by the controlling unit 501. The time parameter of the block is retrieved by the controlling unit 501 for a data loss prevention, a wear leveling operation or a garbage collection, which will be described later.

According to the time parameter stored in each block of the flash memory 505 and the current time parameter, the controlling unit 501 performs data loss prevention. Since the data are possibly lost after they have been written into the flash memory 505 for a time period (e.g. 3 months), the controlling unit 501 may judge whether the data of an old block needs to be moved to a new block according to a difference between the current time parameter and the time parameter of the old block.

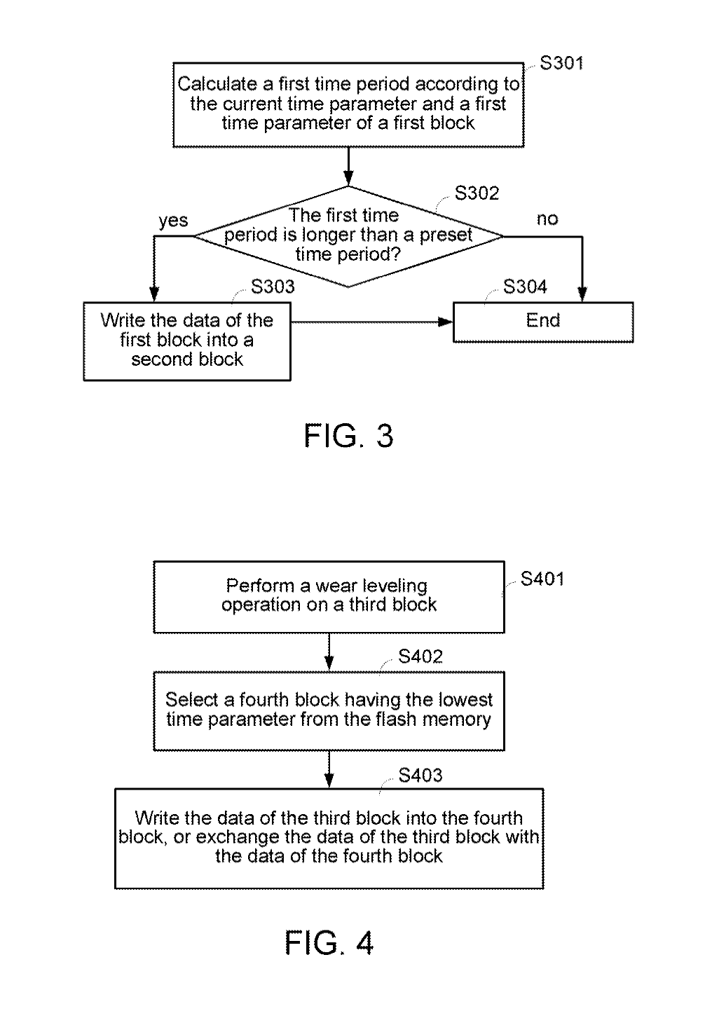

FIG. 3 is a flowchart illustrating a process of performing data loss prevention by using a time parameter according to an embodiment of the present invention. When data stored in any block of the flash memory 505 are erased or data are written into any block of the flash memory 505, the time parameter corresponding to the block will be recorded in the block by the controlling unit 501. The time parameter is also retrieved by the controlling unit 501. As a consequence, the controlling unit 501 will calculate a first time period according to the current time parameter and a first time parameter of a first block (Step S301). The, the step S302 is performed to judge whether the first time period is longer than a preset time period (e.g. 2.5 months). If the first time period is shorter than the preset time period, it means that the data stored in the first block will not be lost. Meanwhile, no operation is performed on the first block (Step S304). Whereas, if the first time period is longer than the preset time period, the data of the first block are written into a second block (Step S303). Meanwhile, the data loss prevention is completed, and thus the process is ended (Step S304).

Since the data of the first block have been written into the second block and the time parameter corresponding to the second block is the current time parameter, the possibility of losing data of the second block is minimized. In addition, after the data have been written into the second block, the data of the first block become invalid data. Meanwhile, the erasing operation may be performed on the first block.

FIG. 4 is a flowchart illustrating a process of performing a wear leveling operation by using the time parameter according to an embodiment of the present invention. When data stored in any block of the flash memory 505 are erased or data are written into any block of the flash memory 505, the time parameter corresponding to the block will be recorded in the block by the controlling unit 501. The time parameter is also retrieved by the controlling unit 501. For performing the wear leveling operation, the erase count of the block may be also taken into consideration. That is, the wear leveling operation may be performed according to the time parameter and the erase count or according to the time parameter only. In this embodiment, the block having the lowest time parameter is also the block having the lowest erase count. That is, the wear leveling operation is performed on the block having the lowest time parameter.

Please refer to FIG. 4. For performing the wear leveling operation on a third block by the controlling unit 501 (Step S401), the controlling unit 501 will select a fourth block having the lowest time parameter from the flash memory 505 (Step S402).

In a case that no data are stored in the fourth block (e.g. the fourth block is a blank block that has been erased), the data of the third block are directly written into the fourth block to implement the wear leveling operation (Step S403). The time parameter of the fourth block is changed to the current time parameter. In addition, after the data have been written into the fourth block, the data of the third block become invalid data. Meanwhile, the erasing operation may be performed on the third block.

Whereas, in a case that the fourth block contains data, the data of the third block and the data of the fourth block are exchanged to implement the wear leveling operation (Step S403). The time parameters of the third block and fourth block are changed to the current time parameter.

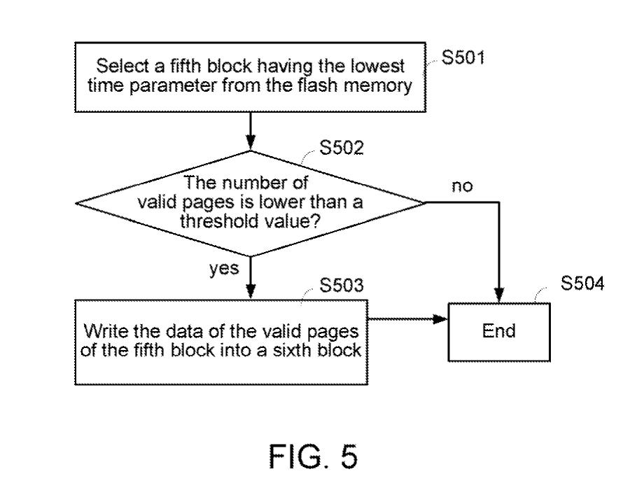

FIG. 5 is a flowchart illustrating a process of performing a garbage collection by using the time parameter according to an embodiment of the present invention. When data stored in any block of the flash memory 505 are erased or data are written into any block of the flash memory 505, the time parameter corresponding to the block will be recorded in the block by the controlling unit 501. The time parameter is also retrieved by the controlling unit 501. For performing the garbage collection, the erase count of the block may be also taken into consideration. That is, the garbage collection may be performed according to the time parameter and the erase count or according to the time parameter only. In this embodiment, the block having the lowest time parameter is also the block having the lowest erase count, and the garbage collection is preferentially performed on this block.

Please refer to FIG. 5. Firstly, a fifth block having the lowest time parameter is selected from the flash memory 505 by the controlling unit 501 in order to perform the garbage collection (Step S501). The controlling unit 501 will judge whether the number of valid pages of the fifth block is lower than a threshold value (Step S502). If the number of valid pages of the fifth block is higher than the threshold value, it means that no garbage collection is necessarily performed on the fifth block, and thus the process is ended (Step S504). Whereas, if the number of valid pages of the fifth block is lower than the threshold value, it means that the garbage collection needs to be performed on the fifth block. Consequently, the data of the valid pages of the fifth block are written into a sixth block (Step S503). Meanwhile, the garbage collection is completed, and thus the process is ended (Step S504).

After the process of performing the garbage collection on the fifth block is completed, the data of the fifth block become invalid data. Meanwhile, the fifth block may be erased and reused.

From the above descriptions, the time parameter corresponding to each block is used as an index, and a data loss prevention, a wear leveling operation or a garbage collection is performed according to the index. In the prior art, only the erase count is used as the index. Whereas, according to the data control method of the present invention, the wear leveling operation or the garbage collection may be performed without the need of using the erase count as the index.

In the above embodiments, the time signal T generated by the real time clock component 503 is used as the time parameter. Nevertheless, the way of acquiring the time parameter is not restricted to the time signal T. Hereinafter, some other approaches of acquiring the time parameter will be illustrated.

For example, when a file is written to the solid state drive 50, the information of the file is also transmitted from the host 52 to the controlling unit 501. The information of the file includes the writing time of the file. The writing time of the file may be retrieved by the controlling unit 501 to be used as the time parameter. In other words, when a file is written from the host 52 to the solid state drive 50 through the external bus 60, the controlling unit 501 will use the writing time of the file as the time parameter, and then count up time. Therefore, when data stored in any block of the flash memory 505 are erased or data are written into any block of the flash memory 505, the time parameter corresponding to the block will be recorded in the block by the controlling unit 501. The time parameter is also retrieved by the controlling unit 501. According to the time parameter, the controlling unit 501 performs a data loss prevention, a wear leveling operation or a garbage collection.

Moreover, the host 52 is in communication with the solid state drive 50 according to a communication protocol, so that a time signal may be transmitted from the host 52 to the solid state drive 50 via the communication protocol. The controlling unit 501 may acquire the time parameter according to the time signal outputted from the host 52, and then count up time. According to the time parameter, the controlling unit 501 performs a data loss prevention, a wear leveling operation or a garbage collection.

Moreover, in a case that no time signal is acquired by the controlling unit 501, the controlling unit 501 may count the total erase count of the flash memory 505. That is, once one block of the flash memory 505 is erased, the time parameter is automatically increased by a value “1”. If the total erase count of all blocks of the flash memory 505 is 1,500, the time parameter is 1,500.

According to undue experiments, if the difference between the time parameter corresponding to a specified block and the current time parameter is 200, the data have been written into the specified block for more than 2.5 months. As a consequence, if the controlling unit 501 judges that the time difference between the time parameter of a specified block and the current time parameter is greater than 200, the data loss prevention is performed on the specified block. Similarly, according to the lowest time parameter of the specified block, the wear leveling operation or the garbage collection may be performed on the specified block.

From the above descriptions, the present invention provides a data control method of a flash memory. By using a time parameter as an index, a data loss prevention, a wear leveling operation or a garbage collection may be performed

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A solid state drive, comprising:
a flash memory comprising plural blocks, wherein each block comprises plural pages; and
a controlling unit in communication with the flash memory, wherein when data of a specified block are erased or data are written into the specified block, the controlling unit provides a time parameter to the specified block, wherein the controlling unit performs a data loss prevention, a wear leveling operation or a garbage collection according to the time parameter.

2. The solid state drive according to claim 1, wherein the solid state drive further comprises a real time clock component in communication with the controlling unit for generating a time signal to the controlling unit, so that the time signal is used as the time parameter.

3. The solid state drive according to claim 1, wherein the solid state drive is in communication with a host, wherein when a file is written from the host to the solid state drive, a time signal is retrieved from the writing time of the file to be used as the time parameter.

4. The solid state drive according to claim 1, wherein the solid state drive is in communication with a host according to a communication protocol, wherein a time signal outputted from the host to the controlling unit is used as the time parameter.

5. The solid state drive according to claim 1, wherein a total erase count of all blocks of the flash memory is counted by the controlling unit to be used as the time parameter.

6. The solid state drive according to claim 1, wherein a first time period is calculated according to a current time parameter and a first time parameter of a first block, wherein if the first time period is longer than the preset time period, the data of the first block are written into a second block so as to perform the data loss prevention.

7. The solid state drive according to claim 1, wherein for performing the wear leveling operation on a third block, the controlling unit selects a fourth block having the lowest time parameter from the flash memory, the data of the third block are written into the fourth block or the data of the third block are exchanged with the data of the fourth block.

8. The solid state drive according to claim 1, wherein for performing the garbage collection, the controlling unit selects a fifth block having the lowest time parameter from the flash memory and judges whether the number of valid pages of the fifth block is lower than a threshold value, wherein if the number of valid pages of the fifth block is lower than the threshold value, the data of the valid pages of the fifth block are written into a sixth block.

9. A data control method of a flash memory, the flash memory comprising plural blocks, each block comprising plural pages, the data control method comprising steps of:
providing a time parameter to a specified block when data of the specified block are erased or data are written into the specified block; and
performing a data loss prevention, a wear leveling operation or a garbage collection according to the time parameter.

10. The data control method according to claim 9, wherein the time parameter is a time signal generated by a real time clock component.

11. The data control method according to claim 9, wherein the flash memory is in communication with a host, wherein when a file is written from the host to the flash memory, a time signal is retrieved from the writing time of the file to be used as the time parameter.

12. The data control method according to claim 9, wherein the flash memory is in communication with a host according to a communication protocol, wherein a time signal outputted from the host is used as the time parameter.

13. The data control method according to claim 9, wherein a total erase count of all blocks of the flash memory is counted and used as the time parameter.

14. The data control method according to claim 9, wherein the data loss prevention is performed by steps of:
calculating a first time period according to a current time parameter and a first time parameter of a first block; and
writing the data of the first block into a second block if the first time period is longer than the preset time period.

15. The data control method according to claim 9, wherein the wear leveling operation is performed on a third block by steps of:
selecting a fourth block having the lowest time parameter from the flash memory; and
writing the data of the third block into the fourth block or exchanging the data of the third block with the data of the fourth block.

16. The data control method according to claim 9, wherein the garbage collection is performed by steps:
selecting a fifth block having the lowest time parameter from the flash memory;
judging whether the number of valid pages of the fifth block is lower than a threshold value; and
writing the data of the valid pages of the fifth block into a sixth block if the number of valid pages of the fifth block is lower than the threshold value.
